(19) United States
(12) Patent Application Publication
(10) Pub. No.: US 2011/0010596 A1
(43) Pub. Date: Jan. 13, 2011

(54) TESTABLE CIRCUIT WITH INPUT/OUTPUT CELL FOR STANDARD CELL LIBRARY

(76) Inventors: Tao-Yen Yang, Nantou County (TW); Kun-Chin Huang, Hsinchu County (TW)

Correspondence Address: NORTH AMERICA INTELLECTUAL PROPERTY CORPORATION, P.O. BOX 506, MERRIFIELD, VA, 22116, US

(21) Appl. No.: 12/500,588

(22) Filed: Jul. 9, 2009

(51) Int. Cl. G01R 31/3177; G06F 11/25

(52) U.S. Cl. 714/734; 714/E11.155

(57) ABSTRACT

A testable circuit includes a first function logic, an input output cell including an input/output unit and a first control multiplexer; and a first testing block is provided, wherein the input/output unit has at least a connection terminal. The first control multiplexer has an output port coupled to the connection terminal, a first input port coupled to the first functional logic, and a second input port. The first testing block is coupled between the first functional logic and the second input port, wherein when the testable circuit is under a testing mode, the first control multiplexer couples the second input port to the output port; and when the testable circuit is under a normal mode, the first control multiplexer couples the first input port to the output port.

### BACKGROUND OF THE INVENTION

1. Field of the Invention

The present invention relates to DFT (design for test), and more particularly, to a testable circuit and standard input/output cell (of a standard cell library) which efficiently improve the duty cycle shifted and shorten a required delay time when the testable circuit/IO cell is operated under a functional (normal) mode.

2. Description of the Prior Art

Design for test (DFT) was developed in the 1960s. The technology was developed for reducing the required cost of creating a successful test for an integrated circuit (IC). Conventionally, engineers must insert many logic gates on the input pin(s) and/or on the enable pin of the under-test input/output (IO) cell for shifting out different test results in order to confirm the correctness of the IO cell. However, when the IO cell is shipped and is operated under a user environment (e.g., a functional mode or a normal mode) after verification, the testable circuit including those logic gates will still seriously impact the duty cycle and increase the delay time of the functional path since the circuit path under the testing mode and under the functional mode are the same. This further affects the performance of the testable circuits/IO cell, especially when the whole circuit structure including the IO cell is a high speed structure.

There is therefore a demand to provide a new scheme that efficiently shortens the circuit path when the whole circuit is operated under a functional mode while maintaining the testable properties of the circuits to thereby solve the problems of the conventional schemes.

### SUMMARY OF THE INVENTION

It is therefore one of the objectives of the present invention to provide a testable circuit and an IO cell of a standard cell library to shorten the corresponding circuit paths when the testable design is operated under a functional mode to enhance the efficiency of timing closure and clock duty of testable designs.

According to one exemplary embodiment of the present invention, a testable circuit is provided. The testable circuit includes a first function logic, an input/output cell and a first testing block. Wherein the input/output cell includes an input/output unit and a first control multiplexer, and the input/output unit has at least a connection terminal. The first control multiplexer has an output port coupled to the connection terminal, a first input port coupled to the first functional logic, and a second input port. The first testing block is coupled between the first functional logic and the second input port, wherein when the testable circuit is under a testing mode, the first control multiplexer couples the second input port to the output port, and when the testable circuit is under a normal mode, the first control multiplexer couples the first input port to the output port.

According to another exemplary embodiment of the present invention, an input/output cell deposited in a testable circuit is provided. The input/output cell includes: a mode control pin, a first input pin, a second input pin, and an input/output unit. The mode control pin is implemented for receiving a multiplexer control signal; the first input pin is implemented for receiving a first input signal under a normal mode; the second input pin is implemented for receiving a second signal under a testing mode; the input/output unit has at least a connection terminal; and the first control multiplexer has an output port, a first input port, a second input port and a control port where the output port is coupled to the connection terminal, the first input port is coupled to the first input pin, the second input port is coupled to the second input pin, and the control port is coupled to the mode control pin.

The foregoing has outlined in broad terms the features and technical advantages of the present invention in order that the following detailed description of the invention may be better understood. Additional features and descriptions of the present invention will be described hereinafter which form the subject of the claims of the present invention.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a testable circuit according to an exemplary embodiment of the present invention.

FIG. 2 is a diagram illustrating an exemplary embodiment of a first testing block shown in FIG. 1.

FIG. 3 is a diagram illustrating an exemplary embodiment of a second testing block shown in FIG. 2.

FIG. 4 is a diagram illustrating an input/output cell according to an exemplary embodiment of the present invention.

FIG. 5 is a diagram illustrating an exemplary circuit design using the input/output cell shown in FIG. 4.

FIG. 6 is a diagram illustrating an exemplary comparison between the required time of the conventional design and that of the present invention under different semiconductor processes.

### DETAILED DESCRIPTION

Certain terms are used throughout the following descriptions and claims to refer to particular system components. As one skilled in the art will appreciate, manufacturers may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . . ” The terms “couple” and “couples” are intended to mean either an indirect or a direct electrical connection. Thus, if a first device couples to a second device, that connection may be through a direct electrical connection, or through an indirect electrical connection via other devices and connections.

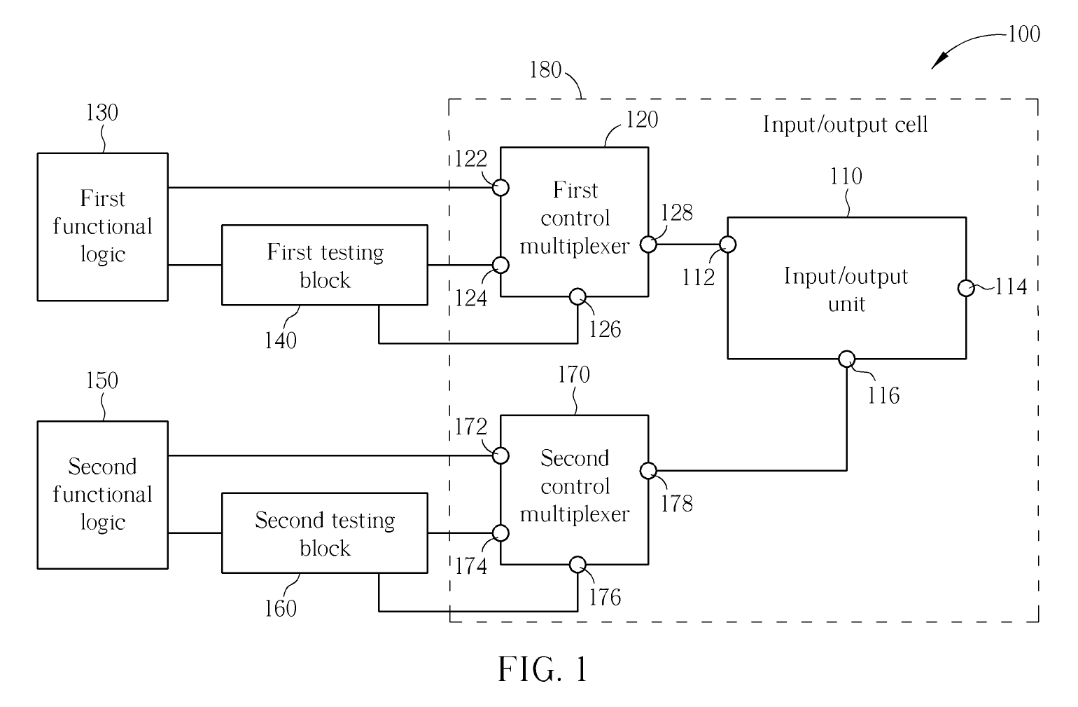

Please refer to FIG. 1, which is a diagram illustrating a testable circuit 100 according to an exemplary embodiment of the present invention. As shown in FIG. 1, the testable circuit 100 employs a circuit scheme capable of shortening the circuit path when the testable circuit 100 is operated under a functional mode; on the other hand, when the testable circuit 100 is operated under a testing mode, the corresponding circuit path under the testing mode will still ensure the validity of the circuit by passing the functional data through the first testing block 140 before it is inputted to a second input port 124 of the first control multiplexer 120. In this exemplary embodiment, the testable circuit 100 includes an input/output cell 180 having an input/output unit 110 and a first control multiplexer 120; wherein the input/output unit 110 has an input terminal 112 coupled to an output port 128 of a first control multiplexer 120 for selectively receiving input data (functional data) passed from a first input port 122 or the second input port 124 to the output port 128 under the control of the first control multiplexer 120.

When the testable circuit 100 is operated under the functional mode, (i.e., the testing process is finished and the testable circuit 100 is shipped), the functional data generated from a first functional logic 130 will be directly transmitted to the first input port 122 of the first control multiplexer 120. In this way, the functional data only needs to pass through the first control multiplexer 120 via the first input port 122 before it is inputted into the input/output unit 110 when the testable circuit 100 is operated under the functional mode. In this exemplary embodiment, the first control multiplexer 120 selectively controls the corresponding circuit path of the functional data to be from the first functional logic 130 to an output terminal 114 of the input/output unit 110 from the first input port 122 or from the second input port 124 (via the first testing block 140) according to a control port 126 of the first control multiplexer 120. Though the control port 126 receives a control signal from the first testing block 140 for controlling the operation of the first control multiplexer 120 according to the exemplary embodiment shown in FIG. 1, the control signal in other exemplary embodiments can be generated in different ways according to different design requirements. The aforementioned description is for illustrative purposes only, and all the alternative designs fall within the scope of the present invention.

As mentioned above, for achieving the testing flow, the first testing block 140 is implemented for ensuring that the input/output unit 110 meets some particular specifications. For instance, the first testing block 140 may include a plurality of multiplexers to achieve the objective of testing the correctness of the input/output unit 110 under different considerations. Please note that the testable circuit 100 of the present invention provides a novel scheme for supplying two circuit paths for an input terminal 112 and/or an enable terminal 116 of the input/out unit 110, thereby shortening the required time of the input/output unit 110 under the functional mode by providing a functional circuit path corresponding to a functional mode while providing a testing circuit path corresponding to the testing mode.

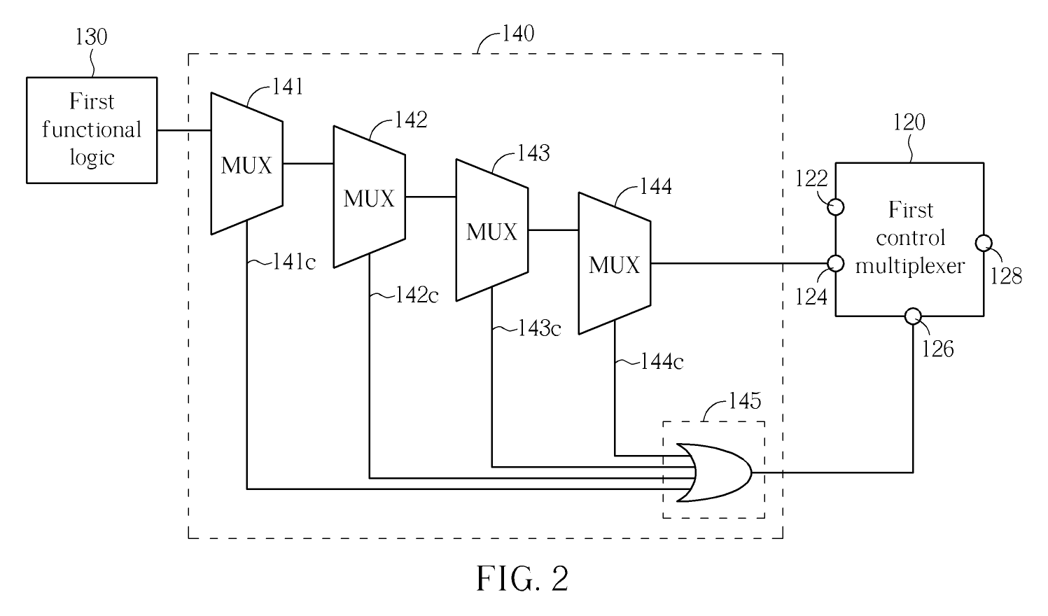

Please refer to FIG. 2, which is a diagram illustrating an exemplary embodiment of the first testing block 140 in FIG. 1. Suppose that the testable circuit 100 provides two circuit paths for the testing mode and the functional mode of the input terminal 112 of the input/output unit 110, respectively. The first testing block 140 corresponding to the circuit path under the testing mode may include at least one multiplexer (MUX) and a control unit 145. In the embodiment shown in FIG. 2, the exemplary first testing block 140 includes four testing multiplexers 141, 142, 143, and 144. As mentioned above, the control unit 145 generates the control signal (e.g., a multiplexer control signal) for the control port 126 of the first control multiplexer, and thereby selectively controls the first control multiplexer 120 to couple the first input port 112 to the output port 128 or couple the second input port 124 to the output port 128. For instance, in an exemplary embodiment shown in FIG. 2, the control unit 145 is implemented using an OR gate with input terminals coupled to control terminals 141c, 142c, 143c, and 144C of the testing multiplexers 141, 142, 143, and 144. The aforementioned description merely discloses a simple embodiment of the present invention; however, all the alternative designs which obey the spirit of the present invention should fall within the scope of the present invention.

Please refer to FIG. 1 again. In real cases, sometimes the input/output unit 110 is bidirectional, and hence equipped with an enable terminal 116 for controlling the output function (e.g., the data flow direction) of the bidirectional input/output unit 110. For example, in one implementation, the bi-directional input/output unit 110 is configured to pass data from the output port 128 to either the first input port 122 or the second input port 124; in another implementation, the bi-directional input/output unit 110 is configured to pass data from either the first input port 122 or the second input port 124 to the output port 128. For matching the requirements of modern robust testable circuit designs/IO cell designs, engineers need to provide a testing circuit by inserting a plurality of multiplexers for testing the correctness of the enable terminal 116 of the input/output unit 110. In this exemplary embodiment, the testable circuit 100 further includes a second functional logic 150, a second testing block 160 and a second control multiplexer 170. Similarly, under the functional mode, the second control multiplexer 170 controls a first input port 172 to couple to an output port 178 of the second control multiplexer 170; under the testing mode, the second control multiplexer 170 controls a second input port 174 to couple to the output port 178 of the second control multiplexer 170. In other words, in an exemplary embodiment of the present invention wherein the input/output unit 110 is bidirectional, the input/output cell 180 of the testable circuit 100 at this time includes the input/output unit 110, the first control multiplexer 120, and the second control multiplexer 170 according to the design requirements. In this way, the correctness of the input/output unit 110 is verified through testing the input/output unit 110 via the second testing block 160. Similarly, with the help of the implemented second control multiplexer n170, the required time of the functional mode can be effectively shortened as well. Further details are illustrated as follows.

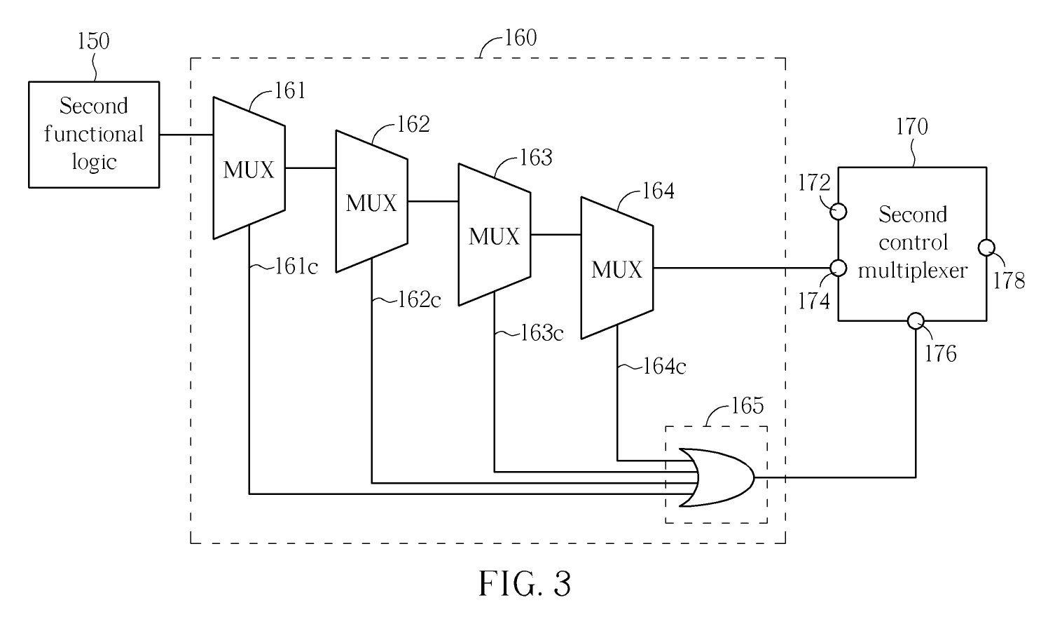

Please refer to FIG. 3 in conjunction with FIG. 1. FIG. 3 is a diagram illustrating an exemplary embodiment of the second testing block 160 in FIG. 3. As shown in FIG. 3, the second testing block 160 includes a plurality of testing multiplexers 161, 162, 163 and 164, and a control unit 165. It should be noted that the number of testing multiplexers shown in FIG. 3 is for illustrative purposes only, and is not meant to be a limitation of the present invention. In this exemplary embodiment, the control unit 165 is coupled to the control port 176 of the second control multiplexer 170 for controlling the second control multiplexer 170 to selectively enable a functional circuit path corresponding to the functional mode or enable a testing circuit path via the second testing block 160 corresponding to the testing mode. Since the operational details of the second testing block 170 can be easily understood from the above description of the first testing block 140 shown in FIG. 2, further description is omitted for brevity here.

In brief, the testable circuit proposed by the present invention has a functional circuit path and a testing circuit path, and the functional circuit path between a functional logic and a first input port of the control multiplexer under the normal mode (i.e., the functional mode) is shorter than the testing circuit path between the functional logic and a second input port of the control multiplexer under the testing mode. The aforementioned description is for illustrative purpose only and is not meant to be a limitation of the present invention. For instance, when the input/output unit of the testable circuit is one-directional, the testable circuit 100 may only include the first functional logic 130, the first testing block 140, the first control multiplexer 120 and the input/output unit 110 for providing the input terminal 112 with a functional circuit path shorter than its testing circuit path. All the alternative design variations fall within the scope of the present invention.

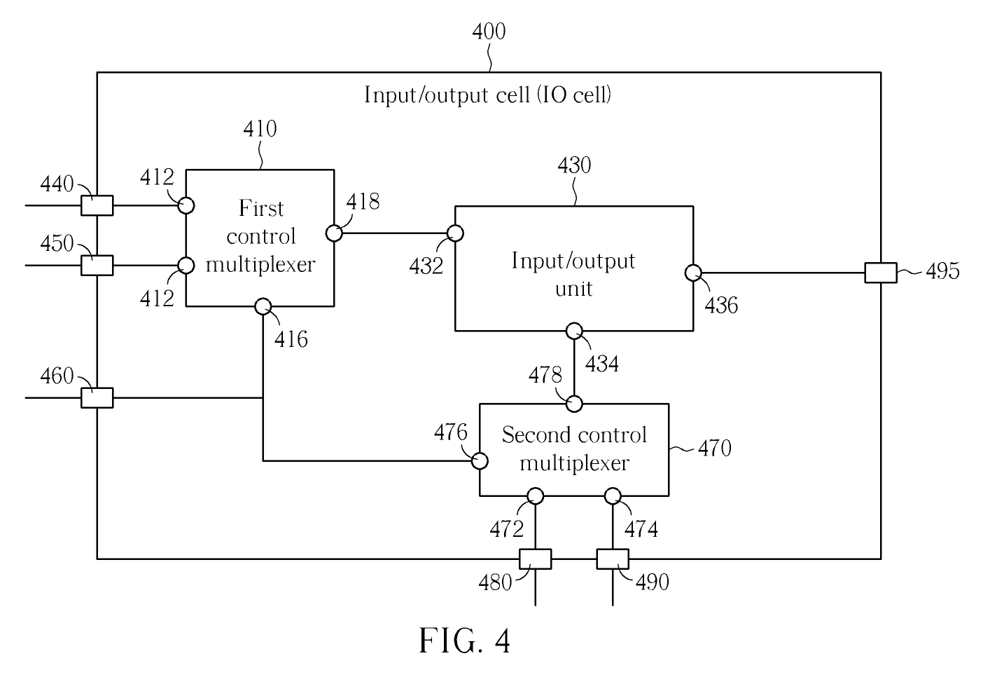

Please refer to FIG. 4, which is a diagram illustrating an input/output cell (IO cell) 400 of a standard cell library according to an exemplary embodiment of the present invention. In this exemplary embodiment, the input/output cell 400 includes, but is not limited to, a first control multiplexer 410, a second control multiplexer 470, and an input/output unit 430. Furthermore, the input/output cell 400 has a first input pin 440 corresponding to a first input port 412 of the first control multiplexer 410 and a second input pin 450 corresponding to a second input port 414 of the first control multiplexer 410, and a mode control pin 460. The mode control pin 460 receives a control signal (e.g., a multiplexer control signal) and delivers the control signal to a control port 416 of the first control multiplexer 410 for controlling the first control multiplexer 410 to selectively couple the first input port 412 to an output port 418, or couple the second input port 414 to the output port 418 of the first control multiplexer 412.

Similarly, in a case where the input/output cell 400 is a bidirectional input/output cell, the input/output unit 400 may further include a second multiplexer 470, a third input pin 480 corresponding to a first input port 472 of the second control multiplexer 470, and a fourth input pin 490 corresponding to a second input port 474 of the second control multiplexer 470. The second control multiplexer 470 controls an output port 478 (which is coupled to an enable terminal 434 of the input/output unit 430) to couple to the first input port 472 or the second input port 470 according to a control signal received at the mode control pin 460. Since the operational details of the input/output cell 400 with the first input pin 440, the second input pin 450, the mode control pin 460 and/or the third input pin 480 and the fourth input pin 490 can be easily understood from the above description directed to the testable circuit 100; further description is omitted here for brevity. In addition, the input/output cell 400 may belong to a novel stand cell library corresponding to the present invention, and the input/output cell 400 includes an output pin 495 for outputting signals. Since the function and operation of the output pin 495 are well known to people skilled in this art, further description is omitted.

In simple terms, in contrast to the conventional IO cell design, the input/output cell 400 of the present invention provides a novel IO cell where at least one port of an input terminal 432 and an enable terminal 434 of the inner input/output unit 430 has a shortened circuit path under the functional mode. For instance, in FIG. 4, the functional data may be directly input into the input/output unit 430 via the first input port 412 of the first control multiplexer 410 under the functional mode. Hence, the corresponding circuit path of the input terminal 432 and/or the enable terminal 434 of the input/output unit 430 under the functional mode is much shorter than that under the testing mode.

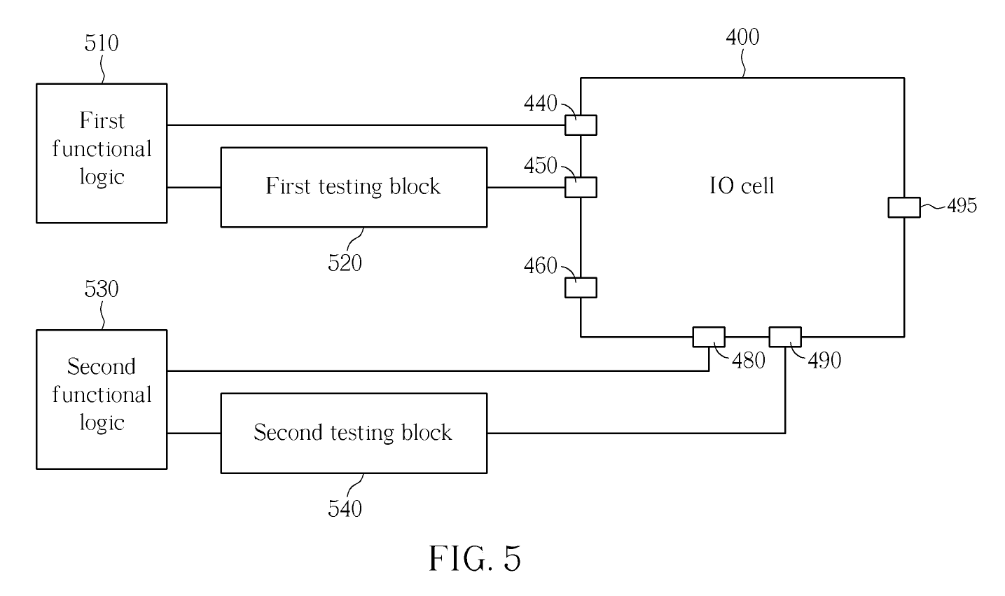

Please refer to FIG. 5 in conjunction with FIG. 4. FIG. 5 is a diagram illustrating an exemplary circuit design using the input/output cell (IO cell) 400 shown in FIG. 4. In this case, the IO cell 400 of a specified standard cell library of the present invention is a bidirectional IO cell. Therefore, the first pin 440 is coupled to a first functional logic 510 for providing a corresponding functional circuit path under the functional mode, the second pin 450 of the IO cell 400 is coupled to the first testing block 520; and the first functional logic 510 and the first testing block accomplish a testing circuit path for verifying the correctness of the input function of the IO cell 400. Since there may be a plurality of testing elements for testing the IO cell 400 inside the first testing block 520, the testing circuit path linking the first functional logic 510, the first testing block 520 and the second pin 450 is longer than the functional circuit path between the first functional logic 510 and the first pin 440.

Furthermore, the third pin 480 is coupled to a second functional logic 530 for providing a corresponding functional circuit path under the functional mode while the fourth pin 450 of the IO cell 400 is coupled to the second testing block 520 to thereby accomplish a corresponding testing circuit path for verifying the correctness of the IO cell 400. As can be seen, the testing circuit path passing through the second testing block 540 to the fourth pin 490 is longer than the functional circuit path corresponding to the third pin 480 due to the fact that the second testing block 540 includes one or more testing elements such as multiplexers.

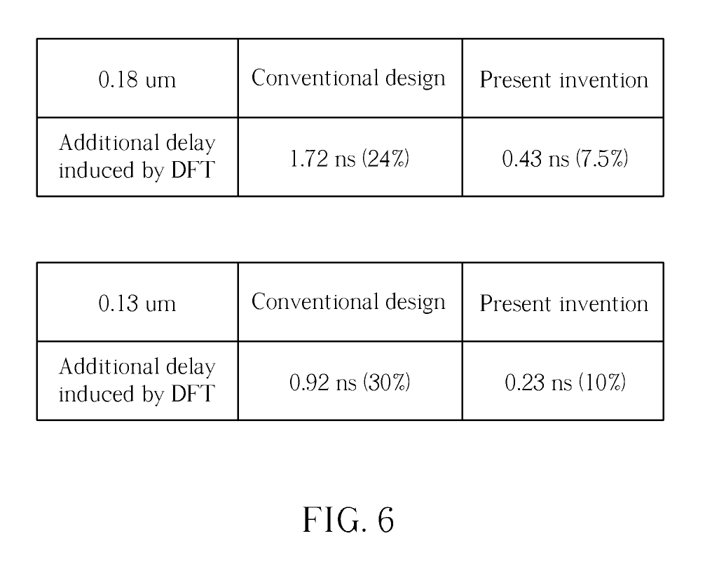

In conclusion, the exemplary IO cell and the testable circuit of the present invention employ a novel testable circuit scheme by shortening the required time and circuit path of at least one of the input terminal and the enable terminal and hence improve the performance while simultaneously enhancing the efficiency of timing closure. Please refer to FIG. 6, which is a diagram illustrating an exemplary comparison between the required time of the conventional design and that of the present invention under different semiconductor processes. It is clear from the diagram that the disclosed novel testable circuit design of the present invention effectively reduces the required time. Therefore, the testable circuit design of the present invention is applicable to high-speed applications.

Those skilled in the art will readily observe that numerous modifications and alterations of the device and method may be made while retaining the teachings of the invention.

What is claimed is:

1. A testable circuit, comprising:
a first functional logic;
an input/output cell, comprising:
an input/output unit, having at least a connection terminal; and
a first control multiplexer, having an output port coupled to the connection terminal, a first input port coupled to the first functional logic, and a second input port; and
a first testing block, coupled between the first functional logic and the second input port;
wherein when the testable circuit is under a testing mode, the first control multiplexer couples the second input port to the output port; and when the testable circuit is under a normal mode, the first control multiplexer couples the first input port to the output port.

2. The testable circuit of claim 1, wherein the first testing block comprises:
at least one multiplexer, coupled between the first functional logic and the first control multiplexer; and
a control unit, coupled to control ports of the at least one multiplexer and the first control multiplexer, for generating a multiplexer control signal to a control port of the first control multiplexer according to multiplexer control signal(s) of the at least one multiplexer.

3. The testable circuit of claim 2, wherein the control unit is an OR gate.

4. The testable circuit of claim 1, wherein the input/output unit is a bidirectional input/output unit.

5. The testable circuit of claim 4, wherein the bi-directional input/output unit comprises an input terminal, an output terminal, and an enable terminal, and the connection terminal is one of the input terminal and the enable terminal.

6. The testable circuit of claim 1, wherein the input/output cell further comprises:
a second control multiplexer, having an output port coupled to the enable terminal, a first input port coupled to a second functional logic, and a second input port.

7. The testable circuit of claim 6, further comprising:
the second functional logic; and
a second testing block, coupled between the second functional logic and the second input port of the second control multiplexer;
wherein the connection terminal is the enable pin; when the testable circuit is under the testing mode, the second control multiplexer couples the second input port of the second control multiplexer to the output port of the second control multiplexer; and when the testable circuit is under the normal mode, the second control multiplexer couples the first input port of the second control multiplexer to the output port of the second control multiplexer.

8. The testable circuit of claim 1, wherein a circuit path between the first functional logic and the first input port of the first control multiplexer under the normal mode is shorter than a circuit path between the first functional logic and the second input port of the first control multiplexer under the testing mode.

9. An input/output cell deposited in a testable circuit, comprising:
a mode control pin, for receiving a multiplexer control signal;
a first input pin, for receiving a first input signal under a normal mode;
a second input pin, for receiving a second signal under a testing mode;
an input/output unit, having at least a connection terminal; and
a first control multiplexer, having an output port coupled to the connection terminal, a first input port coupled to the first input pin, a second input port coupled to the second input pin, and a control port coupled to the mode control pin.

10. The input/output cell of claim 9, wherein the input/output unit is a bi-directional input/output unit.

11. The input/output cell of claim 10, wherein the bi-directional input/output unit comprises an input terminal, an output terminal, and an enable terminal, the input/output cell further comprises an output pin coupled to the output terminal, and the connection terminal is one of the input terminal and the enable terminal.

12. The input/output cell of claim 11, wherein the connection terminal is the input terminal, and the input/output cell further comprises:
a third input pin, for receiving a third input signal under the normal mode;
a fourth input pin, for receiving a fourth signal under the testing mode; and
a second control multiplexer, having an output port coupled to the enable terminal, a first input port coupled to the third input pin, a second input port coupled to the fourth input pin, and a control port coupled to the mode control pin.
